(19) United States
(12) Patent Application Publication
(10) Pub. No.: US 2013/0234565 A1
(43) Pub. Date: Sep. 12, 2013

(54) PIEZOELECTRIC VIBRATOR, OSCILLATOR, ELECTRONIC DEVICE, AND RADIO-CONTROLLED TIMEPIECE

(71) Applicant: SEIKO INSTRUMENTS INC., Chiba-shi (JP)

(72) Inventor: Kiyoshi ARATAKE, Chiba-shi (JP)

(73) Assignee: SEIKO INSTRUMENTS INC., Chiba-shi (JP)

(21) Appl. No.: 13/791,187

(22) Filed: Mar. 8, 2013

(30) Foreign Application Priority Data
Mar. 9, 2012 (JP) 2012-053548

(51) Int. Cl. H01L 41/047; H01L 41/29

(52) U.S. Cl. CPC H01L 41/047; H01L 41/29
USPC 310/366; 29/25.35

(57) ABSTRACT

Provided are a piezoelectric vibrator, an oscillator, an electronic device, and a radio-controlled timepiece capable of preventing lowering of an electrical characteristic of a routing electrode during the frequency adjustment with respect to a piezoelectric vibrator whose frequency can be adjusted by irradiating a laser beam onto a weight metal film formed on a distal end of a vibrating arm portion. In a piezoelectric vibrator, a routing electrode is arranged in an offset manner toward one side with respect to a center line of a base substrate in the lateral width direction, and a piezoelectric vibrating piece is arranged in an offset manner toward a side opposite to the routing electrode with respect to the center line of the base substrate in the lateral direction.

### RELATED APPLICATIONS

This application claims priority under 35 U.S.C. §119 to Japanese Patent Application No. 2012-053548 filed on Mar. 9, 2012, the entire content of which is hereby incorporated by reference.

### BACKGROUND OF THE INVENTION

1. Field of the Invention

The present invention relates to a piezoelectric vibrator, an oscillator, an electronic device, and a radio-controlled timepiece.

2. Description of the Related Art

For example, as disclosed in JP-A-2010-119127, it is often the case that a piezoelectric vibrator which makes use of crystal or the like is used as a time source, a timing source for control signals, a reference signal source or the like in a mobile phone or a personal digital assistant.

As this kind of piezoelectric vibrator, there has been known a piezoelectric vibrator where a tuning-fork-type piezoelectric vibrating piece is hermetically sealed in a package where a cavity is formed. The package has the structure where a pair of glass substrates in which a recessed portion is formed on one of the glass substrates overlaps each other and is directly bonded to each other thus providing the structure where the recessed portion functions as a cavity. Further, the piezoelectric vibrating piece includes a pair of vibrating arm portions which is arranged parallel to each other, and a base portion to which longitudinal proximal end sides of both vibrating arm portions are integrally fixed. The base portion of the piezoelectric vibrating piece is fixed to a surface of one glass substrate, and both vibrating arm portions of the piezoelectric vibrating piece vibrate in the direction that the vibrating arm portions approach each other or are separated from each other with predetermined resonance frequency using proximal end sides thereof as starting points.

Further, through electrodes which penetrate the glass substrate from one surface side to the other surface side of the glass substrate are formed on the glass substrate. The base portion of the piezoelectric vibrating piece and the through electrodes are electrically connected with each other by routing electrodes which extend in the longitudinal direction of the vibrating arm portions on a surface of the glass substrate. As a package of a piezoelectric vibrator, besides the glass package explained above, a ceramic package and the like are known.

### SUMMARY OF THE INVENTION

Conventionally, there has been known the structure where a weight metal film for frequency adjustment is formed on a distal end of a piezoelectric vibrating piece. Usually, a manufacturing process of a piezoelectric vibrator includes a frequency adjustment step where it is confirmed whether or not the frequency of the piezoelectric vibrator falls within a range of nominal frequency for a device, and the frequency is adjusted when the frequency does not fall within the range of nominal frequency for the device. In this frequency adjustment step, the frequency of the piezoelectric vibrator can be increased by evaporating a portion of the above-mentioned weight metal film by the irradiation of a laser beam.

However, recently, along with the miniaturization of a piezoelectric vibrator, a distance between a vibrating arm portion and a routing electrode which is arranged parallel to the vibrating arm portion is liable to become narrow. It has been found that, in such a case, splashed weight metal adheres to the routing electrode at the time of laser beam irradiation. When the splashed weight metal adheres to the routing electrode, there arises a possibility that the routing electrode is short-circuited or an electrical characteristic is lowered. Further, when positioning accuracy of a mounting position of the piezoelectric vibrating piece is low, there exists a possibility that the laser beam is directly irradiated to the routing electrode.

That is, in the prior art, splashed weight metal adheres to the routing electrode or a laser beam is directly irradiated to the routing electrode and hence, there exists a possibility that an electrical characteristic of the routing electrode is lowered each time the frequency adjustment step is performed. Further, no effective countermeasures have been taken so far for overcoming such a drawback which inventors of the present invention have recently discovered.

Accordingly, it is an object of the present invention to provide a piezoelectric vibrator, an oscillator, an electronic device, and a radio-controlled timepiece capable of preventing lowering of an electrical characteristic of a routing electrode during the frequency adjustment with respect to a piezoelectric vibrator whose frequency can be adjusted by irradiating a laser beam onto a weight metal film formed on a distal end of a vibrating arm portion.

To achieve the above-mentioned objects, according to one aspect of the present invention, there is provided a piezoelectric vibrator which includes: a package which is formed by bonding a plurality of substrates in a thickness direction; a piezoelectric vibrating piece which is housed in a cavity formed in the package and includes vibrating arm portions which vibrate with predetermined frequency; a weight metal film for frequency adjustment which is formed on a distal end side of the vibrating arm portion; a through electrode which electrically connects an external electrode formed on an outer surface of the package and the inside of the cavity; and a routing electrode which is formed on an inner surface of the cavity and electrically connects the through electrode and the piezoelectric vibrating piece with each other, at least one routing electrode extending substantially parallel to a longitudinal direction of the vibrating arm portion in the vicinity of an inner wall of the cavity, wherein the piezoelectric vibrating piece is mounted in the cavity such that a center line of the piezoelectric vibrating piece is positioned on a side opposite to the routing electrode extending substantially parallel to the longitudinal direction of the vibrating arm portion with respect to a center line of the cavity which extends in the longitudinal direction.

In this manner, by mounting the piezoelectric vibrating piece in the cavity such that the center line of the piezoelectric vibrating piece is positioned on a side opposite to the routing electrode extending substantially parallel to a longitudinal direction of the vibrating arm portion with respect to the center line of the cavity which extends in the longitudinal direction of the vibrating arm portion, a distance between the vibrating arm portion and the routing electrode can be widened. Therefore, a possibility of weight metal which splashes at the time of laser beam irradiation adhering to the routing electrode or a laser beam is directly irradiated to the routing electrode can be largely decreased. Accordingly, it is possible to provide a piezoelectric vibrator capable of preventing lowering of an electrical characteristic of the routing electrode at the time of frequency adjustment. It is often the case that at least one routing electrode extends substantially parallel to the longitudinal direction of the vibrating arm portion in the vicinity of the inner wall of the cavity. To explain this point, firstly, by taking into account various conditions at the time of mounting the piezoelectric vibrator on a printed circuit board (a connection position at which the piezoelectric vibrator is connected to a circuit, a space and the like), arranging the external electrodes in the vicinity of an end portion of an outer surface of the package so that a pair of external electrodes which corresponds to different polarities respectively is formed in the vicinity of the end portion of the outer surface of the package at positions spaced farthest apart from each other is unavoidable. In this case, the through electrodes which correspond to the external electrodes respectively are arranged at positions spaced apart from each other in the inside of the cavity. As a result, in order to electrically connect the through electrodes and the piezoelectric vibrating piece with each other, it is necessary to pull around a long distance at least one routing electrode from the through electrode to the piezoelectric vibrating piece. Further, in order to prevent the routing electrode from being exposed to the laser beam irradiation, it is necessary to pull around the routing electrode in a region as distant as possible from the vibrating arm portion. Accordingly, the usual routing electrode is in a situation where forming the routing electrode in the vicinity of the inner wall of the cavity is unavoidable.

The above-mentioned piezoelectric vibrator is also characterized in that, the relationship of S>W/2 is established assuming a distance between the center line of the cavity which extends in the longitudinal direction and the center line of the piezoelectric vibrating piece as S and a width of the routing electrode extending substantially parallel to the longitudinal direction of the vibrating arm portion as W. Because of this technical feature, the possibility of adhesion of weight metal to the routing electrode and the possibility of exposure of the routing electrode to laser beam irradiation can be further decreased. That is, it is considered that the greater the width of the routing electrode, the greater the possibility of adhesion of weight metal and the possibility of exposure to laser beam irradiation become. However, according to the extensive studies made by the inventors of the present invention, by setting the positional relationship between the piezoelectric vibrating piece and the routing electrode as set forth above, even when the width of the routing electrode is increased, the position of the piezoelectric vibrating piece is changed correspondingly and hence, the possibility of adhesion of weight metal to the routing electrode and the possibility of exposure of the routing electrode to laser beam irradiation can be further decreased. The numerical value of W/2 is a numerical value based on an experiment carried out by the inventors of the present invention to prove the advantage of the present invention. Further, assuming W as “a width of a region where the routing electrode can be formed”, W may be set such that 2S>W is satisfied.

According to another aspect of the present invention, there is provided an oscillator where the above-mentioned piezoelectric vibrator is electrically connected to an integrated circuit as an oscillation element.

According to still another aspect of the present invention, there is provided an electronic device where the above-mentioned piezoelectric vibrator is electrically connected to a timer part.

According to still another aspect of the present invention, there is provided a radio-controlled timepiece where the above-mentioned piezoelectric vibrator is electrically connected to a filter part.

The above-mentioned oscillator, electronic device and radio-controlled timepiece include the piezoelectric vibrator which is excellent in operation reliability and hence, it is possible to provide an oscillator, an electronic device and a radio-controlled timepiece having high performance.

As described above, according to the preset invention, it is possible to provide a piezoelectric vibrator, an oscillator, an electronic device, and a radio-controlled timepiece capable of preventing lowering of an electrical characteristic of a routing electrode during the frequency adjustment with respect to a piezoelectric vibrator whose frequency can be adjusted by irradiating a laser beam onto a weight metal film formed on a distal end of a vibrating arm portion.

### BRIEF DESCRIPTION OF THE DRAWINGS

FIG. 1 is a perspective view showing the external appearance of a piezoelectric vibrator;

FIG. 2 is a constitutional view showing the inside of the piezoelectric vibrator shown in FIG. 1, and is also a plan view of the piezoelectric vibrator in a state where a lid substrate is removed;

FIG. 3 is a cross-sectional view of the piezoelectric vibrator taken along a line A-A in FIG. 2;

FIG. 4 is an exploded perspective view of the piezoelectric vibrator shown in FIG. 1;

FIG. 5 is a flowchart of a manufacturing method of the piezoelectric vibrator;

FIG. 6 is an exploded perspective view of a wafer body;

FIG. 7 is a constitutional view showing one embodiment of an oscillator;

FIG. 8 is a constitutional view showing one embodiment of an electronic device; and

FIG. 9 is a constitutional view showing one embodiment of a radio-controlled timepiece.

### DESCRIPTION OF THE PREFERRED EMBODIMENTS

### (Piezoelectric Vibrator)

Hereinafter, a piezoelectric vibrator according to an embodiment of the present invention is explained in conjunction with drawings.

In the explanation made hereinafter, the explanation is made assuming a first substrate as a base substrate wafer and a second substrate as a lid substrate wafer. Further, assume a bonding surface of a base substrate where the base substrate is bonded to the lid substrate as an upper surface (inner surface) U, and a surface of the base substrate on a side opposite to the upper surface U as a lower surface L.

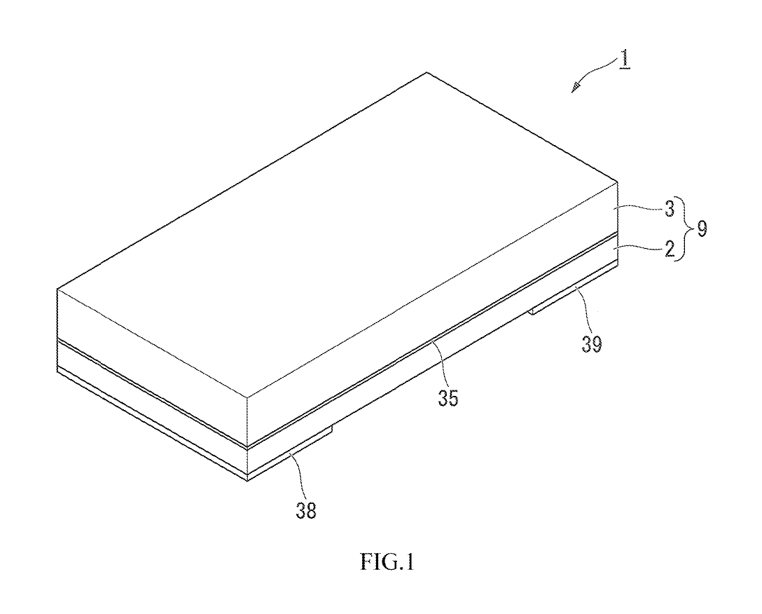

FIG. 1 is a perspective view showing the external appearance of the piezoelectric vibrator.

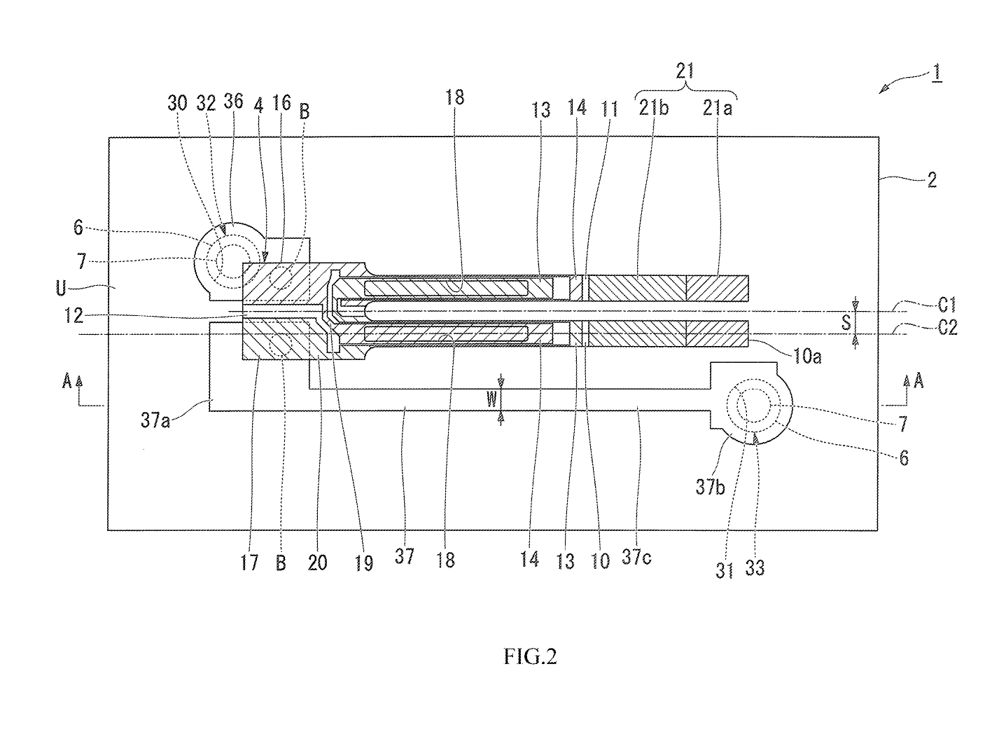

FIG. 2 is a constitutional view showing the inside of the piezoelectric vibrator, and is also a plan view showing the piezoelectric vibrator in a state where the lid substrate is removed.

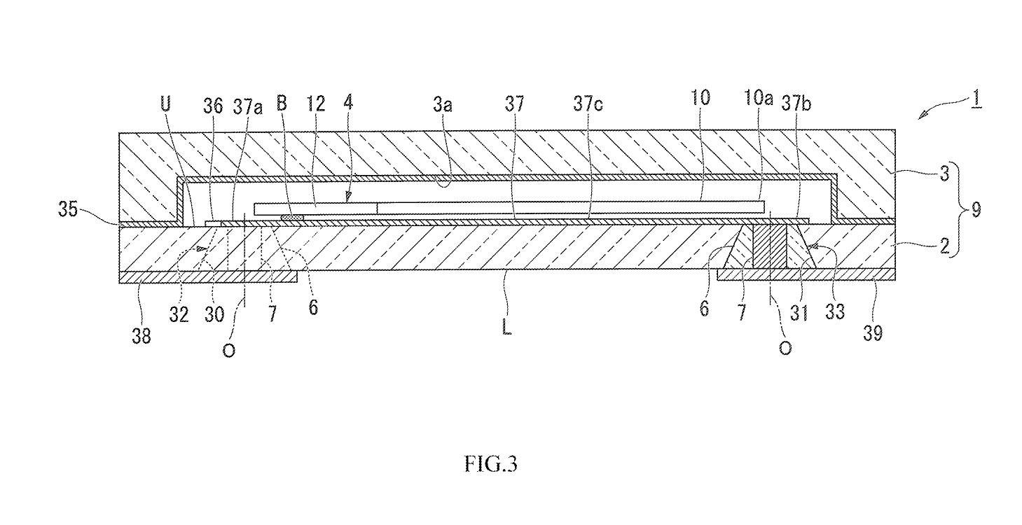

FIG. 3 is a cross-sectional view of the piezoelectric vibrator taken along a line A-A in FIG. 2.

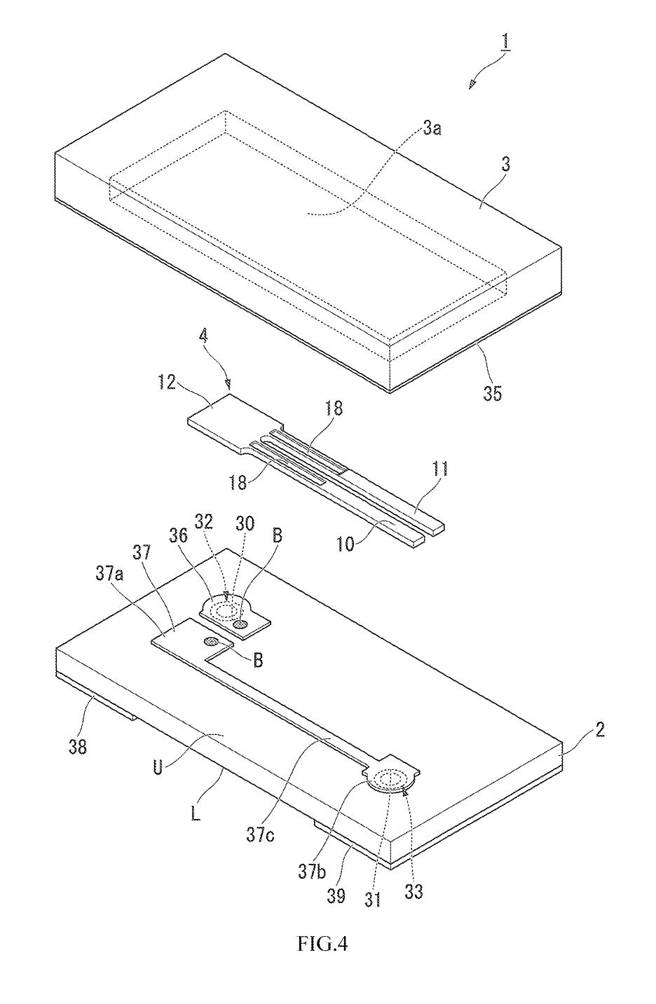

FIG. 4 is an exploded perspective view of the piezoelectric vibrator shown in FIG. 1.

In FIG. 4, to facilitate the understanding of the drawings, excitation electrodes 13, 14, routing electrodes 19, 20, mount electrodes 16, 17, and a weight metal film (adjusting film) 21 described later are omitted.

As shown in FIG. 1 to FIG. 4, the piezoelectric vibrator 1 of this embodiment is a surface-mounted-type piezoelectric vibrator 1 which includes a package 9 where a base substrate (first substrate) 2 having a rectangular shape as viewed in a plan view and a lid substrate (second substrate) 3 having a rectangular shape as viewed in a plan view are bonded to each other by anodic bonding by way of a bonding film 35, and a piezoelectric vibrating piece 4 which is housed in a cavity 3a of the package 9.

### (Piezoelectric Vibrating Piece)

The piezoelectric vibrating piece 4 is a tuning-fork-type vibrating piece which is made of a piezoelectric material such as crystal, lithium tantalate, or lithium niobate, and the piezoelectric vibrating piece 4 is vibrated when a predetermined voltage is applied thereto. The piezoelectric vibrating piece 4 includes a pair of vibrating arm portions 10, 11 which is arranged parallel to each other, a base portion 12 to which proximal end sides of the pair of vibrating arm portions 10, 11 are integrally fixed, and groove portions 18 which are formed on both main surfaces of the pair of vibrating arm portions 10, 11 respectively. The groove portion 18 is formed in the vibrating arm portion 10, 11 along the longitudinal direction of the vibrating arm portion 10, 11 and extends from a proximal end side of the vibrating arm portion 10, 11 to an area in the vicinity of an intermediate portion of the vibrating arm portion 10, 11.

The excitation electrodes 13, 14 and the routing electrodes 19, 20 are made of chromium (Cr) which is the same material used for forming background layers of the mount electrodes 16, 17 described later. Accordingly, the excitation electrodes 13, 14 and the routing electrodes 19, 20 can be formed simultaneously at the time of forming the background layers of the mount electrodes 16, 17.

The excitation electrodes 13, 14 are electrodes which make the pair of vibrating arm portions 10, 11 vibrate in the direction that the vibrating arm portions 10, 11 approach each other or are separated from each other with predetermined resonance frequency. The first excitation electrode 13 and the second excitation electrode 14 are formed on outer surfaces of the pair of vibrating arm portions 10, 11 by patterning in a state where the first excitation electrode 13 and the second excitation electrode 14 are electrically separated from each other.

The mount electrodes 16, 17 are respectively formed of a laminated film consisting of a Cr film and a gold (Au) film. The mount electrode 16, 17 is formed in such a manner that the Cr film which exhibits favorable adhesiveness with crystal is formed as a background layer and, thereafter, the thin Au film is formed on a surface of the Cr film as a finishing layer.

A weight metal film 21 is formed on surfaces of distal end portions of the pair of vibrating arm portions 10, 11 respectively for making a frequency of the vibrating arm portions 10, 11 fall within a range of nominal frequency of a device. The weight metal film 21 is formed of a rough adjustment film 21a which is used for roughly adjusting the frequency and a fine adjustment film 21b which is used for finely adjusting the frequency. By performing the frequency adjustment using the rough adjustment film 21a and the fine adjustment film 21b, it is possible to make the frequency of the pair of vibrating arm portions 10, 11 fall within a range of nominal frequency of the device.

### (Package)

As shown in FIG. 1 to FIG. 4, the base substrate 2 and the lid substrate 3 are substrates made of a glass material such as soda-lime glass, for example, which can be bonded to each other by anodic bonding, and are formed into an approximately plate shape. The cavity 3a which houses the piezoelectric vibrating piece 4 therein is formed on a bonding surface side of the lid substrate 3 where the lid substrate 3 is bonded to the base substrate 2.

A bonding film 35 for anodic bonding is formed on the whole of a bonding surface side of the lid substrate 3 where the lid substrate 3 is bonded to the base substrate 2. That is, the bonding film 35 is formed on a picture frame region around the cavity 3a in addition to the whole inner surface of the cavity 3a. Although the bonding film 35 of this embodiment is made of aluminum (Al), the bonding film 35 may be made of silicon (Si), Cr or the like. As described later, the bonding film 35 and the base substrate 2 are bonded to each other by anodic bonding thus sealing the cavity 3a in vacuum.

As shown in FIG. 3, in the piezoelectric vibrator 1, the piezoelectric vibrating piece 4 is mounted on an upper surface U of the base substrate 2 where the cavity 3a is formed. Accordingly, the piezoelectric vibrator 1 includes a pair of through electrodes 32, 33 which penetrates the base substrate 2 in the thickness direction and makes the inside of the cavity 3a and the outside of the piezoelectric vibrator 1 conductive with each other.

These through electrodes 32, 33 are formed in the base substrate 2 having a rectangular shape as viewed in a plan view such that, on the upper surface U, the through electrode 32 is positioned at one end portion of the base substrate 2 in the longitudinal widthwise direction, and the through electrode 33 is positioned at the other end portion of the base substrate 2. One through electrode 32 is arranged at a position where the through electrode 32 faces the base portion 12 of the piezoelectric vibrating piece 4 in an opposed manner. The other through electrode 33 is arranged in the vicinity of either one of the vibrating arm portions 10, 11 of the piezoelectric vibrating piece 4, for example, a distal end portion 10a of the vibrating arm portion 10, and is arranged at a position offset from the distal end portion 10a in the lateral widthwise direction orthogonal to the longitudinal widthwise direction of the base substrate 2.

These through electrodes 32, 33 are arranged in through holes 30, 31 which penetrate the base substrate 2, and each through electrode 32, 33 is formed of a metal pin 7 which electrically connects the piezoelectric vibrating piece 4 and the outside to each other, and a cylindrical body 6 which is filled in a space defined between the through hole 30, 31 and the metal pin 7. Although the explanation is made hereinafter by taking the through electrode 32 as an example, the same goes for the through electrode 33. Further, the electrical connection among the through electrode 33, a routing electrode 37 and an external electrode 39 is set substantially equal to the electrical connection among the through electrode 32, a routing electrode 36 and the external electrode 39.

As shown in FIG. 3, the through hole 30 is formed such that an inner diameter of the through hole 30 is gradually increased from an upper surface U side to a lower surface L side, and a cross-sectional shape of the through hole 30 including a center axis O is formed into a tapered shape.

The metal pin 7 is a conductive rod-shaped member made of a metal material such as silver (Ag), a Ni alloy or Al, and is formed by forging or by press-forming. The metal pin 7 is preferably made of metal whose linear expansion coefficient is close to a linear expansion coefficient of a glass material for forming the base substrate 2 such as an alloy (42 alloy) containing 58 weight % of iron (Fe) and 42 weight % of Ni, for example.

The cylindrical body 6 is formed by baking glass frit in a paste form. The metal pin 7 is arranged at the center of the cylindrical body 6 so as to penetrate the cylindrical body 6, and the cylindrical body 6 is firmly and fixedly mounted on the metal pin 7 and the through hole 30.

The pair of routing electrodes 36, 37 is formed on an upper surface U side of the base substrate 2 by patterning. One routing electrode 36 is formed at a position where the routing electrode 36 covers the through electrode 32 and faces the base portion 12 of the piezoelectric vibrating piece 4 in an opposed manner.

One end portion 37a of the other routing electrode 37 is formed on one end portion of the base substrate 2 in the longitudinal widthwise direction at a position where one end portion 37a is arranged adjacent to the routing electrode 36 and faces the base portion 12 of the piezoelectric vibrating piece 4 in an opposed manner. The other end portion 37b of the routing electrode 37 is formed on the other end portion of the base substrate 2 in the longitudinal widthwise direction at a position where the other end portion 37b covers the through electrode 33. Here, the vibrating arm portions 10, 11 of the piezoelectric vibrating piece 4 are provided such that the vibrating arm portions 10, 11 are positioned inside one end portion 37a of the routing electrode 37 and inside the other end portion 37b of the routing electrode 37 in the longitudinal widthwise direction of the base substrate 2. That is, the vibrating arm portions 10, 11 of the piezoelectric vibrating piece 4 are arranged inside the routing electrode 37 along the longitudinal widthwise direction of the base substrate 2.

Further, a strip-shaped portion 37c which extends parallel to the vibrating arm portion 10 of the piezoelectric vibrating piece 4 is formed between one end portion 37a and the other end portion 37b of the routing electrode 37. The strip-shaped portion 37c is, as shown in the drawing, positioned in the vicinity of an inner wall of the cavity 3a.

On one end portion of the base substrate 2 in the longitudinal widthwise direction, a tapered bump (mount portion) B made of Au or the like is formed on the pair of routing electrode 36 and the routing electrode 37 (one end portion 37a), and the pair of routing electrodes 36, 37 is mounted on the pair of mount electrodes 16, 17 which is formed on the base portion 12 of the piezoelectric vibrating piece 4 by making use of the bumps B. Due to such a constitution, one mount electrode 16 of the piezoelectric vibrating piece 4 is made conductive with one through electrode 32 via one routing electrode 36, and the other mount electrode 17 is made conductive with the other through electrode 33 via the other routing electrode 37.

Due to such a constitution, the piezoelectric vibrating piece 4 is configured such that the base portion 12 is mounted on the bumps B formed on one end portion of the base substrate 2 in the longitudinal widthwise direction, the vibrating arm portions 10, 11 extend from the base portion 12 toward the other end portion of the base substrate 2 in the longitudinal widthwise direction, and these vibrating arm portions 10, 11 are formed with a gap therebetween in the lateral widthwise direction of the base substrate 2.

A pair of external electrodes 38, 39 is formed on the lower surface L of the base substrate 2. The pair of external electrodes 38, 39 is formed on both end portions of the base substrate 2 in the longitudinal widthwise direction respectively, and is electrically connected to the pair of through electrodes 32, 33 respectively.

In operating the piezoelectric vibrator 1 having such a constitution, a predetermined drive voltage is applied to the external electrodes 38, 39 formed on the base substrate 2. Due to such applying of the drive voltage, it is possible to apply a voltage to the first excitation electrode 13 and the second excitation electrode 14 of the piezoelectric vibrating piece 4 so that the pair of vibrating arm portions 10, 11 can be vibrated in the direction that the vibrating arm portions 10, 11 approach each other or are separated from each other with predetermined frequency. By making use of the vibrations of the pair of vibrating arm portions 10, 11, the piezoelectric vibrator 1 can be used as a time source, a timing source of a control signal, a reference signal source or the like.

In the above-mentioned piezoelectric vibrator 1, the piezoelectric vibrating piece 4 is arranged such that a center line C1 of the piezoelectric vibrating piece 4 in the widthwise direction (in the direction that the vibrating arm portions 10, 11 are arranged parallel to each other) is offset toward a side opposite to the strip-shaped portion 37c of the routing electrode 37 with respect to a center line C2 of the cavity 3a in the lateral widthwise direction. That is, the piezoelectric vibrator 1 is characterized in that the piezoelectric vibrating piece 4 is mounted in the cavity 3a such that the center line C1 of the piezoelectric vibrating piece 4 is positioned on a side opposite to the strip-shaped portion 37c of the routing electrode 37 with respect to the center line C2 of the cavity 3a which extends in the longitudinal direction. Due to such a constitution, a distance between the routing electrode 37 and the vibrating arm portions 10, 11 can be widened and hence, there exists no possibility that weight metal adheres to the strip-shaped portion 37c of the routing electrode 37 particularly or a laser beam is irradiated to the strip-shaped portion 37c at the time of performing a frequency adjustment step. Accordingly, there exists no possibility that an electrical characteristic of the routing electrode is lowered. It is preferable that an offset amount S of the center line C1 of the piezoelectric vibrating piece 4 in the widthwise direction with respect to the center line C2 of the cavity 3a in the lateral widthwise direction is set to satisfies the relationship of S>W/2 with respect to a width W of the strip-shaped portion 37c of the routing electrode 37. That is, the larger the width W of the strip-shaped portion 37c, the higher the possibility of adhesion of weight metal and the possibility of exposure to laser beam irradiation become. However, by setting the offset amount S corresponding to the width W of the strip-shaped portion 37c as described above, it is possible to more surely prevent the adhesion of weight metal and the like. According to extensive studies made by the inventors of the present invention, it is confirmed that, when the offset amount S is set to satisfy the relationship of S=W/3, although the above-mentioned advantageous effect can be acquired to some extent compared to a case where the center line C1 is not offset at all with respect to the center line C2, the advantageous effect is not yet sufficient. On the other hand, it is confirmed that, when the offset amount S is set to satisfy the relationship of S>W/2, the above-mentioned advantageous effect can be acquired sufficiently. Further, by modifying S>W/2 into 2S>W, an upper limit of the width W of the strip-shaped portion 37c can be decided. That is, it is difficult to easily change a width size of a package when a mounting environment and business model are taken into consideration. In the same manner, although an offset amount S of the piezoelectric vibrating piece 4 can be also suitably selected, a selectable width range is limited when it is necessary to take into account conditions such as a condition that the piezoelectric vibrating piece 4 should not be brought into contact with the inner wall of the cavity 3a, and a condition that a bonding state between the mount electrodes 16, 17 and the metal bumps B should be maintained. Accordingly, a maximum value of the width W of the strip-shaped portion 37c can be set using the above-mentioned formula and hence, different from the prior art, it is unnecessary to decide a position and a size of the strip-shaped portion 37c by trial and error by taking into account scattering of weight metal and the like whereby it is possible to more easily provide the piezoelectric vibrator 1 which acquires the above-mentioned advantageous effects. Instead of grasping W as a width of the strip-shaped portion 37c, W may be grasped as “a region where the strip-shaped portion 37c can be formed (a width measured from the inner wall of the cavity 3a)”. That is, provided that the strip-shaped portion 37c is arranged in a region of W which satisfies the above-mentioned formula, the above-mentioned advantageous effects can be acquired irrespective of the width of the strip-shaped portion 37c.

### (Method of Manufacturing Piezoelectric Vibrator)

Next, a method of manufacturing the above-mentioned piezoelectric vibrator is explained in conjunction with a flowchart.

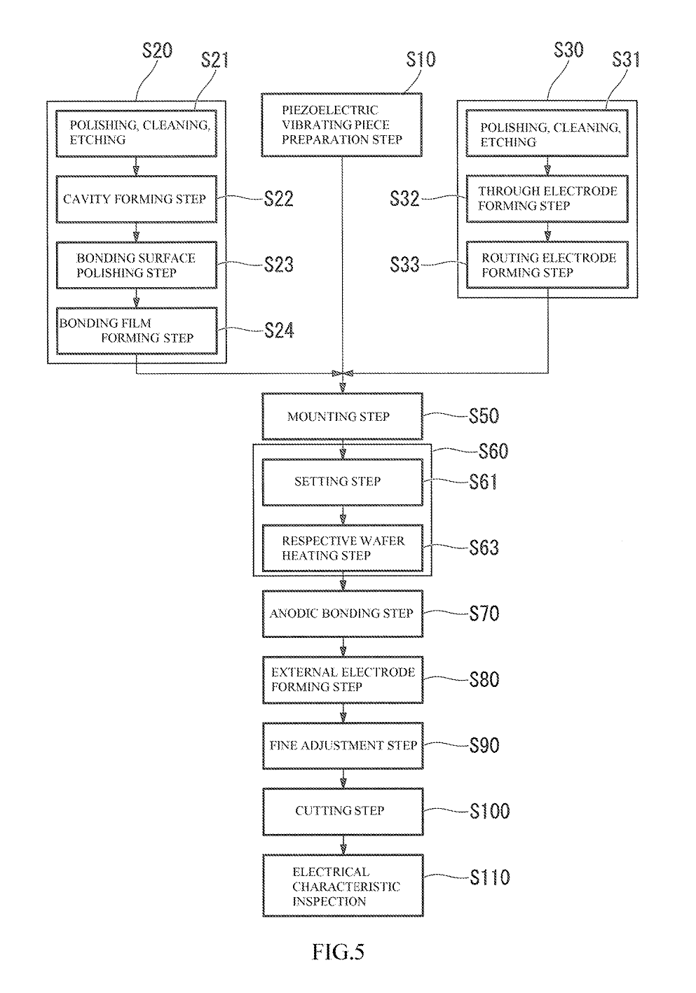

FIG. 5 is a flowchart of a method of manufacturing the piezoelectric vibrator of this embodiment.

The method of manufacturing the piezoelectric vibrator according to this embodiment mainly includes a piezoelectric vibrating piece preparation step S10, a lid substrate wafer preparation step S20, a base substrate wafer preparation step S30, and an assembling step (S50 and steps succeeding S50). Among these steps, the piezoelectric vibrating piece preparation step S10, the lid substrate wafer preparation step S20 and the base substrate wafer preparation step S30 may be carried out simultaneously.

### (Piezoelectric Vibrating Piece Preparation Step S10)

In the piezoelectric vibrating piece preparation step S10, the piezoelectric vibrating piece 4 is prepared. To be more specific, a wafer having a predetermined thickness is formed by slicing a Lambert crystal ore at a predetermined angle and by applying mirror-finish working such as polishing to the sliced Lambert crystal ore. Subsequently, the wafer is patterned using a photolithography technique in accordance with outer shapes of the piezoelectric vibrating pieces 4 and, at the same time, a metal film is formed and patterned thus forming the excitation electrodes 13, 14, the routing electrodes 19, 20, the mount electrodes 16, 17 and the weight metal film 21.

Thereafter, the rough adjustment of the resonance frequency of the piezoelectric vibrating piece 4 is performed. To be more specific, a rough adjustment film 21a of the weight metal film 21 is evaporated by irradiating a laser beam onto the rough adjustment film 21a (see FIG. 2). Due to such treatment, a weight of a distal end side of the pair of vibrating arm portions 10, 11 is reduced and hence, the frequency of the piezoelectric vibrating piece 4 is elevated.

The piezoelectric vibrating piece preparation step S10 is finished with the above-mentioned processing.

### (Lid Substrate Forming Wafer Preparation Step S20)

In the lid substrate forming wafer preparation step S20, a lid substrate forming wafer 50 which becomes the lid substrate later is prepared. Firstly, a disc-shaped lid substrate forming wafer 50 made of soda lime glass is polished to a predetermined thickness and is cleaned and, thereafter, a working degeneration layer which constitutes an outermost surface is removed by etching or the like (S21). Next, in a cavity forming step S22, the plurality of cavities 3a are formed on a bonding surface of the lid substrate forming wafer 50 where the lid substrate forming wafer 50 is bonded to a base substrate forming wafer 40. The cavities 3a are formed by thermal press-molding, etching or the like. Next, in a bonding surface polishing step S23, the bonding surface of the lid substrate forming wafer 50 where the lid substrate forming wafer 50 is bonded to the base substrate forming wafer 40 is polished.

Next, in a bonding film forming step S24, the bonding film 35 (see FIG. 3) made of A1 is formed on the bonding surface of the lid substrate forming wafer 50 where the lid substrate forming wafer 50 is bonded to the base substrate forming wafer 40 described later. The bonding film 35 may be formed on the whole inner surfaces of the cavities 3a in addition to the bonding surface of the lid substrate forming wafer 50 where the lid substrate forming wafer 50 is bonded to the base substrate forming wafer 40. Due to such a step, patterning of the bonding film 35 becomes unnecessary and hence, a manufacturing cost can be reduced. The bonding film 35 may be formed by a film forming method such as sputtering or a CVD. Since the bonding surface polishing step S23 is performed before the bonding film forming step S24, the flatness of the surface of the bonding film 35 is ensured whereby the stable bonding of the lid substrate forming wafer 50 to the base substrate forming wafer 40 can be realized.

### (Base Substrate Forming Wafer Preparation Step S30)

In the base substrate forming wafer preparation step S30, the base substrate forming wafer 40 which becomes the base substrate later is prepared. Firstly, a disc-shaped base substrate forming wafer 40 made of soda lime glass is polished to a predetermined thickness and is cleaned and, thereafter, a working degeneration layer which constitutes an outermost surface is removed by etching or the like (S31).

### (Through Electrode Forming Step S32)

Next, a through electrode forming step S32 where the pairs of through electrodes 32 are formed on the base substrate forming wafer 40 is performed. Although a forming step of the through electrodes 32 is explained hereinafter, the same goes for a forming step of the through electrodes 33.

Firstly, the through holes 30 are formed in the base substrate forming wafer 40 from the lower surface L to the upper surface U by press forming or the like. Next, glass frit is filled in each through hole 30 in a state where the metal pin 7 is inserted into the through hole 30. The glass frit is mainly constituted of powdery glass particles, an organic solvent, and a binder (a fixing agent).

Subsequently, the cylindrical body 6 made of glass, the through hole 30 and the metal pin 7 are integrally formed with each other by baking the glass frit. For example, after conveying the base substrate forming wafer 40 into a baking furnace, the glass frit is baked. Here, an organic solvent, a binder and the like contained in the glass frit are evaporated so that outgases such as carbon monoxide (CO), carbon dioxide (CO₂), and water vapor (H₂O) are generated and are discharged to the outside of the glass frit.

Finally, by forming the upper surface U and the lower surface L of the base substrate forming wafer 40 into a flat surface by polishing respectively while exposing the metal pin 7 to the upper surface U and the lower surface L, the through electrode 32 is formed in the inside of the through hole 30. By forming the through electrode 32, the electric conductivity between the upper surface U side and the lower surface L side of the base substrate forming wafer 40 is ensured and, at the same time, the through hole 30 formed in the base substrate forming wafer 40 can be sealed.

### (Routing Electrode Forming Step S33)

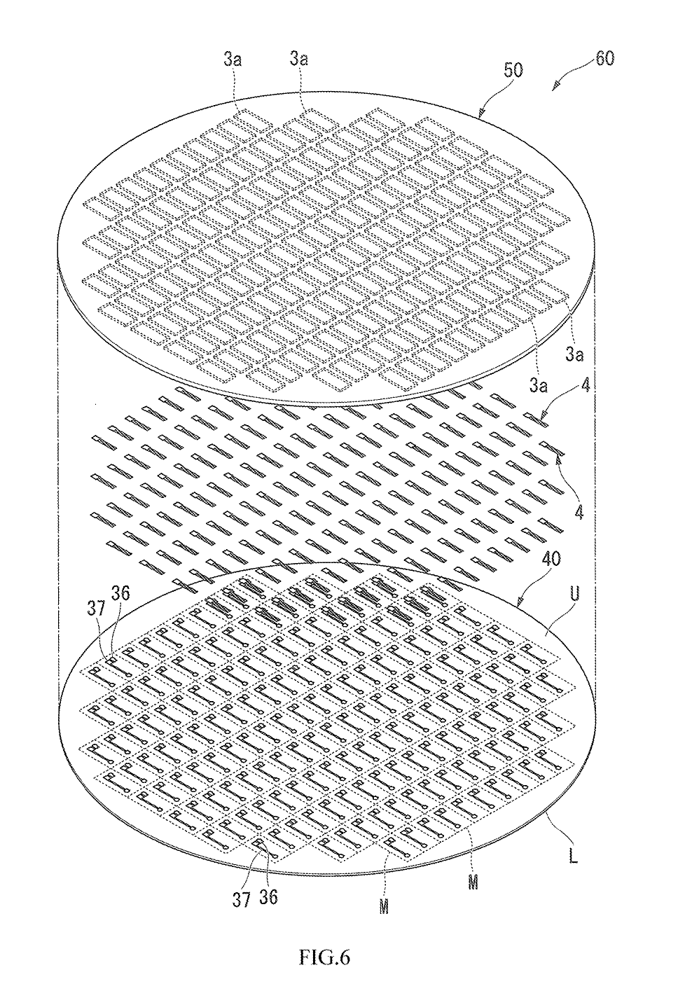

Next, a routing electrode forming step S33 where the plurality of routing electrodes 36, 37 which are electrically connected to the through electrodes respectively are formed on the upper surface U is performed. Further, the tapered bump made of Au or the like is formed on the routing electrodes 36, 37 respectively. In FIG. 6, for facilitating the understanding of the drawing, the bumps are not shown in the drawing. The base substrate forming wafer preparation step S30 is finished at this point of time.

### (Mounting Step S50)

Next, a mounting step S50 where the piezoelectric vibrating pieces 4 are bonded to the routing electrodes 36, 37 formed on the base substrate forming wafer 40 by way of the bumps B respectively is performed. To be more specific, the base portions 12 of the piezoelectric vibrating pieces 4 are placed on the bumps B, and ultrasonic vibrations are applied to the piezoelectric vibrating pieces 4 while heating the bumps B to a predetermined temperature and pushing the piezoelectric vibrating pieces 4 to the bumps B. Due to such an operation, as shown in FIG. 3, the base portions 12 are mechanically and fixedly mounted on the bumps B in a state where the vibrating arm portions 10, 11 of the piezoelectric vibrating pieces 4 float from the upper surface U of the base substrate forming wafer 40.

### (Pre-Heating Step S60)

Subsequently, a pre-heating step S60 where the lid substrate forming wafer 50 and the base substrate forming wafer 40 are pre-heated is performed prior to an anodic bonding step S70. The pre-heating step S60 includes: a setting step S61 where the lid substrate forming wafer 50 and the base substrate forming wafer 40 are set in the inside of a vacuum chamber; and a respective wafer heating step S63 where the lid substrate forming wafer 50 and the base substrate forming wafer 40 are respectively pre-heated.

In the setting step S61, the lid substrate forming wafer 50 and the base substrate forming wafer 40 are set in the inside of a vacuum chamber not shown in the drawing for pre-heating the lid substrate forming wafer 50 and the base substrate forming wafer 40.

In the respective wafer heating step S63, the lid substrate forming wafer 50 and the base substrate forming wafer 40 are heated by a heater provided in the inside of the vacuum chamber.

In the pre-heating step S60, by pre-heating the lid substrate forming wafer 50 and the base substrate forming wafer 40, an organic solvent, a binder, moisture and the like remaining in the inside of the lid substrate forming wafer 50 and the base substrate forming wafer 40 are evaporated so that outgases such as carbon monoxide (CO), carbon dioxide (CO₂) and water vapor (H₂O) are discharged from the lid substrate forming wafer 50 and the base substrate forming wafer 40. Accordingly, in performing the anodic bonding step S70 described later, even when a temperature of the lid substrate forming wafer 50 and a temperature of the base substrate forming wafer 40 are elevated to a bonding temperature, the discharge of outgases can be suppressed.

### (Anodic Bonding Step S70)

Next, the anodic bonding step S70 where the lid substrate forming wafer 50 and the base substrate forming wafer 40 are bonded to each other by anodic bonding is performed. To be more specific, the anodic bonding is performed in accordance with the following steps.

Firstly, the bonding film 35 of the lid substrate forming wafer 50 and the upper surface U of the base substrate forming wafer 40 are brought into contact with each other while maintaining a vacuum state. Then, the lid substrate forming wafer 50 is pressed to the base substrate forming wafer 40 using a pressurizing device not shown in the drawing. Here, a pressing force of the pressurizing device is approximately 500N, for example.

Subsequently, the lid substrate forming wafer 50 and the base substrate forming wafer 40 are heated by a heater not shown in the drawing while being pressed by the pressurizing device. The bonding film 35 of the lid substrate forming wafer 50 is connected to an anode electrode of a power source not shown in the drawing, and an electrode plate not shown in the drawing on which the base substrate forming wafer 40 is placed is connected to a cathode electrode of the power source. A voltage of approximately 500V is applied between the respective electrodes, for example. Due to such an operation, the lid substrate forming wafer 50 and the base substrate forming wafer 40 can be bonded to each other by anodic bonding.

Next, an external electrode forming step S80 is performed. In this step, a conductive material is formed on the lower surface L of the base substrate forming wafer 40 by patterning thus forming plural pairs of external electrodes 38, 39 (see FIG. 3) where each pair of external electrodes 38, 39 is electrically connected to the pair of through electrodes 32, 33 respectively. Due to such a step, the piezoelectric vibrating piece 4 is made conductive with the external electrodes 38, 39 via the through electrodes 32, 33.

Next, a fine adjustment step S90 is performed. In this step, frequency of the individual piezoelectric vibrator sealed in the cavity 3a is finely adjusted in a state of the wafer body 60 such that the frequency falls within a predetermined range. To be more specific, a predetermined voltage is continuously applied to the piezoelectric vibrating piece 4 from the external electrodes 38, 39 shown in FIG. 3 thus measuring frequency while vibrating the piezoelectric vibrating piece 4. In such a state, a laser beam is irradiated to the piezoelectric vibrating piece 4 from the outside of the base substrate forming wafer 40 thus evaporating the fine adjustment film 21b (see FIG. 2) of the weight metal film 21. Accordingly, a weight of a distal end side of the pair of vibrating arm portions 10, 11 is decreased and hence, the frequency of the piezoelectric vibrating piece 4 is increased. By performing the fine adjustment of the frequency of the piezoelectric vibrator 1 as described above, it is possible to make the frequency of the piezoelectric vibrator 1 fall within a range of nominal frequency.

After the fine adjustment of frequency is finished, a cutting step S100 where the bonded wafer body 60 is cut along cutting lines M shown in FIG. 6 is performed. To be more specific, firstly, a UV tape is adhered to the surface of the base substrate forming wafer 40 of the wafer body 60. Next, a laser beam is irradiated to the wafer body 60 from a lid substrate forming wafer 50 side along the cutting line M (scribing). Next, the wafer body 60 is broken by pressing a cutting blade to the wafer body 60 from the surface of the UV tape along the cutting line M (breaking). Thereafter, the UV tape is peeled off by irradiating ultraviolet rays (UV). Due to such an operation, the wafer body 60 can be divided into the plurality of piezoelectric vibrators. The wafer body 60 may be cut by other methods such as dicing.

It may be possible to change the order of steps such that the fine adjustment step S90 is performed after dividing the bonded wafer body 60 into individual piezoelectric vibrators by performing the cutting step S100. However, by performing the fine adjustment step S90 prior to the cutting step S100 as described above, it is possible to perform the fine adjustment of frequency in a form of the wafer body 60 and hence, the fine adjustment of frequency can be performed more efficiently with respect to the plurality of piezoelectric vibrators. Accordingly, the throughput can be enhanced so that this order of steps is preferable.

Thereafter, the electrical characteristic inspection S110 of the inside of the piezoelectric vibrating piece 4 is performed. That is, resonance frequency, a resonance resistance value, drive level characteristics (exciting power dependency of resonance frequency and resonance resistance value) and the like of the piezoelectric vibrating piece 4 are measured and checked. Further, an insulation resistance characteristic and the like of the piezoelectric vibrating piece 4 are also checked. Finally, an appearance inspection of the piezoelectric vibrator is performed so as to make a final check of a size, quality and the like of the piezoelectric vibrator. The manufacture of the piezoelectric vibrator is finished with such processing.

As has been explained heretofore, according to this embodiment, it is possible to provide a piezoelectric vibrator, an oscillator, an electronic device, and a radio-controlled timepiece capable of preventing lowering of an electrical characteristic of the routing electrode during the frequency adjustment with respect to the piezoelectric vibrator whose frequency can be adjusted by irradiating a laser beam onto the weight metal film formed on the distal end of the vibrating arm portion.

### (Oscillator)

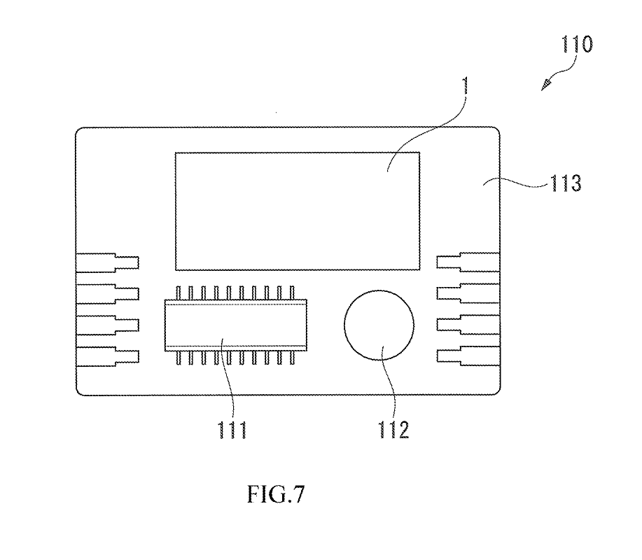

Next, one embodiment of the oscillator according to the present invention is explained in conjunction with FIG. 7.

The oscillator 110 of this embodiment is, as shown in FIG. 7, formed such that the piezoelectric vibrator 1 is electrically connected to an integrated circuit 111 to function as an oscillation element. The oscillator 110 includes a substrate 113 on which an electronic element part 112 such as a capacitor is mounted. The above-mentioned integrated circuit 111 for oscillator is mounted on the substrate 113, and the piezoelectric vibrating piece of the piezoelectric vibrator 1 is mounted on the substrate 113 in the vicinity of the integrated circuit 111. The electronic element part 112, the integrated circuit 111 and the piezoelectric vibrator 1 are electrically connected with each other by a wiring pattern not shown in the drawing. The respective constitutional parts are molded by a resin not shown in the drawing.

In the oscillator 110 having such a constitution, when a voltage is applied to the piezoelectric vibrator 1, the piezoelectric vibrating piece arranged in the inside of the piezoelectric vibrator 1 vibrates. This vibration is converted into an electric signal due to a piezoelectrical characteristic which the piezoelectric vibrating piece possesses, and is inputted to the integrated circuit 111 as the electric signal. Various processing are applied to the inputted electric signal by the integrated circuit 111, and the inputted electric signal is outputted as a frequency signal. Accordingly, the piezoelectric vibrator 1 functions as an oscillation element.

Further, by selectively setting the constitution of the integrated circuit 111, for example, an RTC (real time clock) module or the like corresponding to a request, it is possible to impart, besides a function as a timepiece-use single-function oscillator or the like, a function of controlling an operation date and time of the oscillator or an external device or a function of providing time, calendar and the like to the oscillator 110.

According to the oscillator 110 of this embodiment, the oscillator 110 includes the piezoelectric vibrator 1 with high operational reliability and hence, it is possible to provide the oscillator 110 with excellent reliability.

### (Electronic Device)

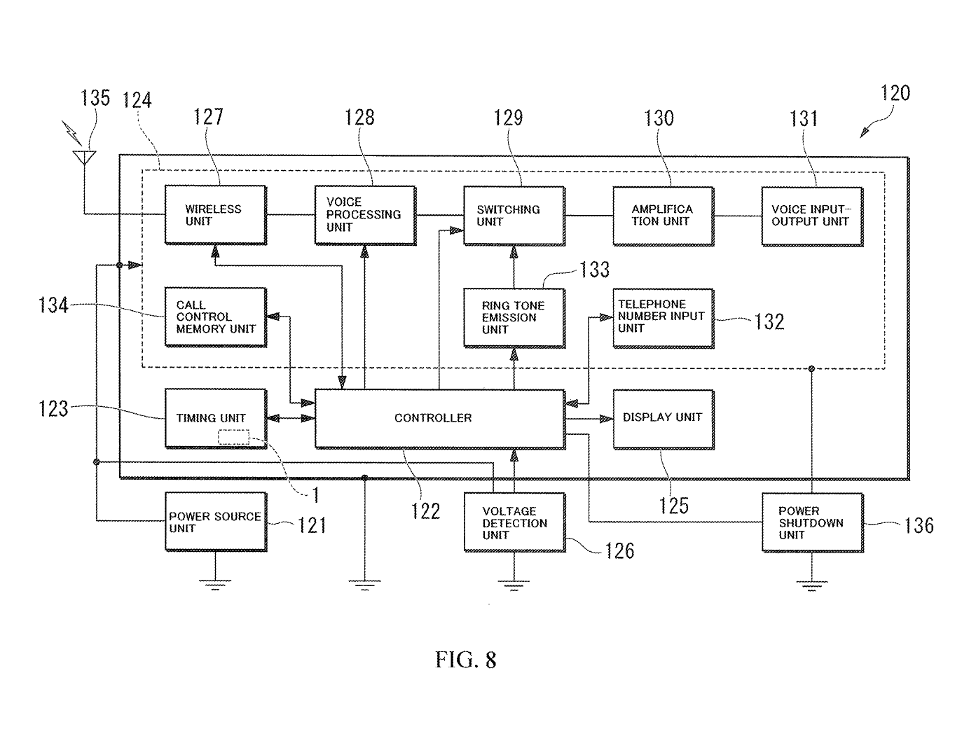

Next, one embodiment of the electronic device according to the present invention is explained in conjunction with FIG. 8. The explanation is made by taking a portable information device 120 which includes the above-mentioned piezoelectric vibrator 1 as an example of the electronic device. Firstly, the portable information device 120 of this embodiment is a device which is represented by a mobile phone, for example, and is a developed or improved form of a conventional wrist watch. The portable information device 120 resembles the wrist watch in appearance. A liquid crystal display is arranged on a portion of the portable information device 120 which corresponds to a dial of the wrist watch, and a present time and the like can be displayed on a screen of the liquid crystal display. Further, when the portable information device 120 is used as a communication device, a user removes the portable information device 120 from his or her wrist, and performs communication in the same manner as a mobile phone of the related art by a speaker and a microphone incorporated into an inner portion of a band. However, the portable information device 120 is remarkably miniaturized and light-weighted compared to the mobile phone of the related art.

Next, the constitution of the portable information device 120 of this embodiment is explained. The portable information device 120 includes, as shown in FIG. 8, a piezoelectric vibrator 1 and a power source part 121 for power supply. The power source part 121 is formed of a lithium secondary battery, for example. To the power source part 121, a control part 122 which performs various controls, a timer part 123 which counts time or the like, a communication part 124 which performs communication with the outside, a display part 125 which displays various information, and a voltage detection part 126 which detects voltages of the respective functional parts are connected to each other in parallel. Electricity is supplied to the respective functional parts from the power source part 121.

The control part 122 performs an operational control of the whole system such as the transmission and the reception of voice data and the measurement, display and the like of a present time by controlling the respective functional parts. Further, the control part 122 includes a ROM in which programs are preliminarily written, a CPU which reads and executes the programs written in the ROM, a RAM which is used as a work area of the CPU and the like.

The timer part 123 includes an integrated circuit which incorporates an oscillation circuit, a register circuit, a counter circuit, an interface circuit and the like therein, and the piezoelectric vibrator 1. When a voltage is applied to the piezoelectric vibrator 1, the piezoelectric vibrating piece vibrates, and the vibrations are converted into an electric signal due to a piezoelectrical characteristic which crystal possesses, and is inputted to the oscillation circuit as the electric signal. An output of the oscillation circuit is binalized and the binalized value is counted by the register circuit and the counter circuit. Then, the transmission/reception of signals is performed between the timer part 123 and the control part 122 via the interface circuit, and a present time, a present date, calendar information and the like are displayed on the display part 125.

The communication part 124 has the substantially same functions as a mobile phone of the related art, and includes a wireless part 127, a voice processing part 128, a switching part 129, an amplifying part 130, a voice inputting/outputting part 131, a telephone number inputting part 132, an incoming call sound generation part 133, and a calling-control memory part 134.

The wireless part 127 performs the transmission/reception of various data such as voice data with a base station through an antenna 135. The voice processing part 128 performs coding and decoding of a voice signal inputted from the wireless part 127 or the amplifying part 130. The amplifying part 130 amplifies a signal inputted from the voice processing part 128 or the voice inputting/outputting part 131 to a predetermined level. The voice inputting/outputting part 131 is formed of a speaker, a microphone or the like, and makes an incoming call sound or a received voice loud or collects voice.

Further, the incoming call sound generation part 133 generates an incoming call sound in response to calling from the base station. The switching part 129 switches the amplifying part 130 connected to the voice processing part 128 to the incoming call sound generation part 133 when a call arrives so that the incoming call sound generated by the incoming call sound generation part 133 is outputted to the voice inputting/outputting part 131 through the amplifying part 130.

Here, the calling control memory part 134 stores a program relating to an incoming/outgoing call control in communication. Further, the telephone number inputting part 132 includes, for example, numeral keys ranging from 0 to 9 and other keys. By pushing these numeral keys or the like, a user can input the telephone number of call destination or the like.

The voltage detection part 126, when a voltage applied to the respective functional parts such as the control part 122 from the power source part 121 becomes lower than a predetermined value, detects such lowering of voltage and notifies the lowering of voltage to the control part 122. The predetermined voltage value at this point of time is a value which is preliminarily set as a minimum voltage necessary for stably operating the communication part 124, and is set to approximately 3V, for example. The control part 122 which receives the notification of lowering of voltage from the voltage detection part 126 prohibits operations of the wireless part 127, the voice processing part 128, the switching part 129 and the incoming call sound generation part 133. Particularly, the operation stop of the wireless part 127 which consumes large power is inevitable. Further, a message that a remaining battery quantity is short so that the communication part 124 is inoperable is displayed on the display part 125.

That is, due to the combined operation of the voltage detection part 126 and the control part 122, an operation of the communication part 124 can be prohibited and a message which indicates the prohibition of the operation of the communication part 124 can be displayed on the display part 125. This display may be formed of a character message. However, as a more intuitive display, a×(bad) mark may be attached to a telephone icon displayed on an upper part of a display screen of the display part 125.

The electronic device is provided with a power source breaking part 136 which can selectively break a power source of a portion relating to a function of the communication part 124. In this case, it is possible to stop the function of the communication part 124 more reliably.

According to the portable information device 120 of this embodiment, the portable information device 120 includes the piezoelectric vibrator 1 with high operational reliability and hence, it is possible to provide the portable information device 120 with excellent reliability.

### (Radio-Controlled Timepiece)

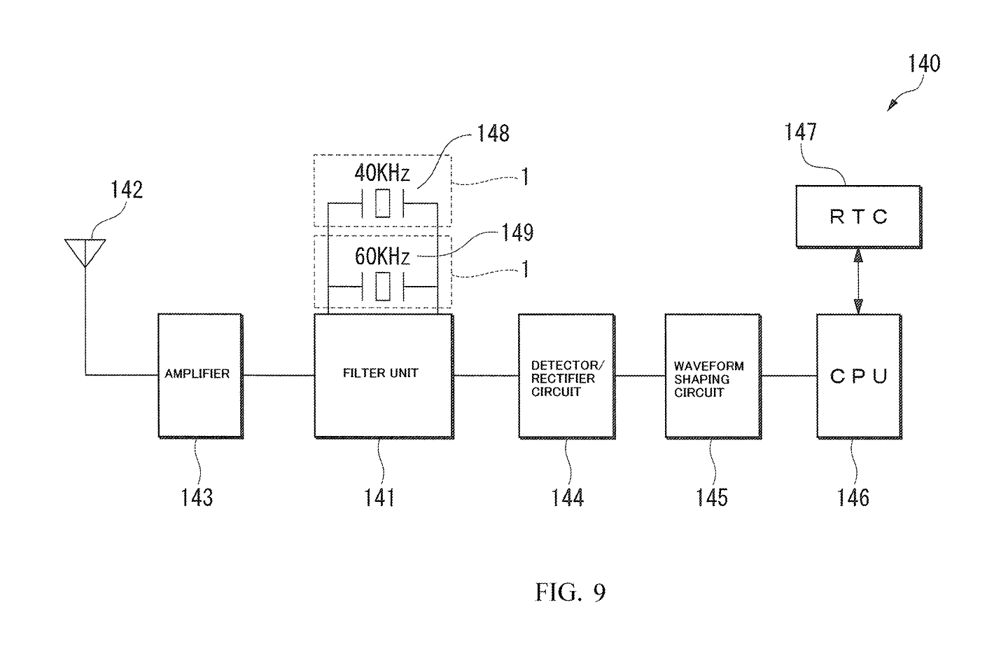

Next, one embodiment of the radio-controlled timepiece according to the present invention is explained in conjunction with FIG. 9.

The radio-controlled timepiece 140 of this embodiment is, as shown in FIG. 9, a timepiece which includes the piezoelectric vibrator 1 which is electrically connected to a filter part 141, and has a function of receiving a standard electric wave containing timepiece information, automatically correcting time to correct time, and displaying the corrected time.

In Japan, transmission installations (transmission stations) which transmit the standard electric wave are located in Fukushima prefecture (40 kHz) and Saga prefecture (60 kHz) and transmit the standard electric waves respectively. A long wave having frequency of 40 kHz or 60 kHz has both of property that the wave propagates on a ground and property that the wave propagates while being reflected between an ionosphere and a ground and hence, the long wave has a wide propagation range whereby the standard electric wave can cover all areas of Japan with the above-mentioned two transmission installations.

The functional constitution of the radio-controlled timepiece 140 is explained in detail hereinafter.

An antenna 142 receives the standard electric wave formed of a long wave having frequency of 40 kHz or 60 kHz. The standard electric wave formed of a long wave is an electric wave which is obtained by AM-modulating a carrier wave having frequency of 40 kHz or 60 kHz by time information called as a time code. The received standard electric wave formed of a long wave is amplified by an amplifier 143, and is filtered by a filter part 141 having a plurality of piezoelectric vibrators 1, and is tuned. The piezoelectric vibrators 1 of this embodiment include crystal vibrator parts 148, 149 having resonance frequency of 40 kHz or 60 kHz as same as the above-mentioned frequency of the carrier frequency respectively.

Further, a filtered signal of predetermined frequency is detected and demodulated by a detection/rectifying circuit 144.

Subsequently, the time code is taken out through a waveform shaping circuit 145, and is counted by a CPU 146. The CPU 146 reads information on a present year, cumulative days, a day of a week, time and the like. The read information is reflected on an RTC 148 so that correct time information is displayed.

The carrier wave has frequency of 40 kHz or 60 kHz and hence, crystal vibrator parts 148, 149 are preferably formed of a vibrator having the above-mentioned tuning-fork structure.

Although the above-mentioned explanation is made with respect to the radio-controlled timepiece used in Japan, the frequencies of standard electric waves of a long wave used overseas differ from the standard electric wave used in Japan. For example, the standard electric wave having frequency of 77.5 kHz is used in Germany. Accordingly, in incorporating the radio-controlled timepiece 140 also compatible with the oversea use into a portable device, the piezoelectric vibrator 1 having frequency different from the frequency used in Japan becomes necessary.

According to the radio-controlled timepiece 140 of this embodiment, the radio-controlled timepiece 140 includes the piezoelectric vibrator 1 with high operational reliability and hence, it is possible to provide the radio-controlled timepiece 140 with excellent reliability.

Here, the present invention is not limited to the above-mentioned embodiment.

In this embodiment, although the constitution which uses a surface-mounted-type glass package where the base substrate 2 and the lid substrate 3 are made of a glass material is exemplified, a ceramic package where the base substrate 2 is made of ceramics and the lid substrate 3 is made of metal, a glass material or the like may be adopted.

Further, although the constitution where the bump B made of gold (Au) or the like is formed on the routing electrodes 36, 37 and the piezoelectric vibrating piece 4 is mounted on the routing electrodes 36, 37 by making use of the bumps B is exemplified, the constitution where the piezoelectric vibrating piece 4 is mounted on the routing electrodes 36, 37 using a conductive adhesive agent in place of the bump B made of gold (Au) or the like may be adopted.

Besides the above-mentioned modifications, it is possible to make a choice among the above-mentioned constitutions and to suitably change the above-mentioned constitution to other constitution without departing from the gist of the present invention.

What is claimed is:

1. A piezoelectric vibrator, comprising:
a package defining a cavity, wherein a center line of the cavity extends in a longitudinal direction;
a piezoelectric vibrating piece housed in the cavity, the piezoelectric vibrating piece comprising vibrating arm portions extending in the longitudinal direction within the cavity and configured to vibrate with predetermined frequency, wherein a center line of the piezoelectric vibrating piece that extends in the longitudinal direction is offset from the center line of the cavity;
a weight metal film for frequency adjustment that is formed on a distal end side of the vibrating arm portion;
a through electrode which electrically connects an external electrode formed on an outer surface of the package and the inside of the cavity; and
a routing electrode which is formed on an inner surface of the cavity and that electrically connects the through electrode and the piezoelectric vibrating piece with each other, wherein the routing electrode is formed on a side of a center line of the cavity that is opposite to a side of the center line to which the center line of the piezoelectric vibrator is offset.

2. The piezoelectric vibrator of claim 1, wherein the routing electrode extends substantially parallel to a longitudinal direction of the vibrating arm portion in the vicinity of an inner wall of the cavity.

3. The piezoelectric vibrator of claim 1, wherein a distance by which the center line of the piezoelectric vibrating piece is offset from the center line of the cavity is greater than half of a width of the routing electrode.

4. The piezoelectric vibrator of claim 1, wherein the package comprises a first substrate and a second substrate above the first substrate, and wherein the cavity is formed between the first and second substrates.

5. The piezoelectric vibrator of claim 1, wherein the routing electrode comprises a first end, a second end positioned above the through hole, and a strip portion extending in the longitudinal direction between the first end and the second end.

6. The piezoelectric vibrator of claim 5, wherein the strip portion comprises a width that is less than two times a distance by which the center line of the piezoelectric vibrating piece is offset from the center line of the cavity.

7. The piezoelectric vibrator of claim 5, wherein a width of the first end is greater than a width of the strip part.

8. The piezoelectric vibrator of claim 1, further comprising:
another through electrode which electrically connects another external electrode formed on the outer surface of the package and the inside of the cavity; and
another routing electrode formed on the inner surface of the cavity on the same side of the center line to which the center line of the piezoelectric vibrator is offset, wherein the another routing electrode electrically connects the another through electrode to the piezoelectric vibrating piece.

9. A piezoelectric vibrator, comprising:
a package comprising:
a first substrate;
a second substrate formed below the first substrate; and
a cavity defined between the first and second substrates, wherein a center line of the cavity extends in a longitudinal direction;
a piezoelectric vibrating piece formed within the cavity, the piezoelectric vibrating piece comprising vibrating arms extending in the longitudinal direction within the cavity and configured to vibrate with predetermined frequency, wherein a center line of the piezoelectric vibrating piece extends in the longitudinal direction and is offset from the center line of the cavity;
a weight metal film for frequency adjustment that is formed on a distal end side of each of the vibrating arms;
a first through electrode formed in the second substrate that provides an electrical connection between an external electrode formed on an outer surface of the package and the inside of the cavity; and
a first routing electrode formed on an upper surface of the second substrate, the first routing electrode comprising:
a first end;
a second end above the first through electrode; and
a strip part extending between the first and second ends in the longitudinal direction, wherein the strip part is offset from the center line of the cavity on a side of center line of the cavity that is opposite to a side of the center line of the cavity to which the center line of the piezoelectric vibrating piece is offset.

10. The piezoelectric vibrator of claim 9, wherein the strip part comprises a width that is less than two times a distance by which the center line of the piezoelectric vibrating piece is offset from the center line of the cavity.

11. The piezoelectric vibrator of claim 9, further comprising:
a second through electrode formed in the second substrate that provides an electrical connection between another external electrode formed on the outer surface of the package and the inside of the cavity; and
a second routing electrode formed on the upper surface of the second substrate over the second through electrode.

12. The piezoelectric vibrator of claim 11, wherein the second routing electrode is formed on the same side of the center line of the cavity to which the center line of the piezoelectric vibrating piece is offset.

13. The piezoelectric vibrator of claim 11, wherein the piezoelectric vibrating piece is mounted above the second routing electrode and the first end of the first routing electrode.

14. The piezoelectric vibrator of claim 9, wherein the first end of the routing electrode comprises a width that is greater than a width of the strip part.

15. A method of manufacturing a piezoelectric vibrator, comprising:
forming a piezoelectric vibrating piece comprising a pair of vibrating arms and a weight metal film formed on the vibrating arms;
forming a first substrate including a cavity defined by a bottom surface of the first substrate;
forming a bonding film on at least a portion of the bottom surface of the first substrate;
forming a second substrate having:
a first through electrode and a second through electrode defined within a thickness of the second substrate;
a first routing electrode formed on an upper surface of the second substrate and having a first end, a second end formed above the first through hole, and a strip part extending in a first direction between the first and second ends; and
a second routing electrode formed on the upper surface of the second substrate above the second through hole;
mounting the piezoelectric vibrating piece above the first end of the first routing electrode and above the second routing electrode such that the vibrating arms extend in parallel to the direction of the strip part;
bonding a portion of the upper surface of the second substrate to a portion of the lower surface of the first substrate such that the piezoelectric vibrating piece is positioned within the cavity,
wherein a center line of the piezoelectric vibrating piece that extends in the first direction is offset from a center line of the cavity that extends in the first direction.

16. The method of claim 15, wherein the piezoelectric vibrating piece is mounted such that the center line of the piezoelectric vibrating piece that extends in the first direction is offset from a center line of the cavity that extends in the first direction by a distance greater than half of a width of the strip part of the first routing electrode.

17. The method of claim 15, wherein the piezoelectric vibrating piece is mounted such that the center line of the piezoelectric vibrating piece that extends in the first direction and the strip part of the first routing electrode are formed on opposite sides of the center line of the cavity.

18. The method of claim 17, wherein the piezoelectric vibrating piece is mounted such that the center line of the piezoelectric vibrating piece that extends in the first direction is offset from a center line of the cavity that extends in the first direction by a distance greater than half of a width of the strip part of the first routing electrode.
